(19) United States
(12) Patent Application Publication
(10) Pub. No.: US 2009/0127602 A1
(43) Pub. Date: May 21, 2009

(54) SEMICONDUCTOR MEMORY DEVICE AND MANUFACTURING METHOD THEREOF

(75) Inventor: Tohru Ozaki, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/252,451

(22) Filed: Oct. 16, 2008

(30) Foreign Application Priority Data
Oct. 17, 2007 (JP) 2007-269911

(51) Int. Cl. H01L 29/51; H01L 21/02; G11C 11/22; H01L 29/68

(52) U.S. Cl. 257/295; 438/3; 365/145; 257/301; 257/E29.17; 257/E29.164; 257/E21.008

(57) ABSTRACT

This disclosure concerns a memory including transistors provided on a substrate; ferroelectric capacitors provided on the transistors, the ferroelectric capacitors respectively including a ferroelectric film provided between a lower electrode and an upper electrode; and a barrier film covering a first side surface of the ferroelectric capacitor, and blocking passing of hydrogen, wherein adjacent two of the ferroelectric capacitors connected in the lower electrode form one capacitor unit, a plurality of the capacitor units connected in the upper electrode form one capacitor chain, the capacitor units are arranged with a deviation of a half pitch of the capacitor unit in adjacent plurality of capacitor chains, and when D1 is a distance between the adjacent ferroelectric capacitors within the capacitor unit, D2 is a distance between the adjacent capacitor chains, and D3 is a distance between the adjacent capacitor units within the capacitor chain, D3 is larger than D1 and D2.

### CROSS-REFERENCE TO RELATED APPLICATION

This application is based upon and claims the benefit of priority from the prior Japanese Patent Applications No. 2007-269911, filed on Oct. 17, 2007, the entire contents of which are incorporated herein by reference.

### BACKGROUND OF THE INVENTION

1. Field of the Invention

The present invention relates to a semiconductor memory device and a manufacturing method thereof, and relates, for example, to an FeRAM (Ferro-electric Random Access Memory).

2. Related Art

In recent years, a ferroelectric random access memory (FeRAM) using a ferroelectric capacitor is focused as one of nonvolatile semiconductor memories. To decrease a size of the FeRAM, a so-called COP (Capacitor On Plug) structure is employed. The COP structure electrically connects an electrode of the ferroelectric capacitor and a source or a drain of a transistor, using a conductive contact plug. The ferroelectric capacitor is easily degraded by a reduction of hydrogen. To prevent a degradation of the ferroelectric capacitor, a structure of covering the ferroelectric capacitor with a hydrogen barrier film is proposed (see Patent Documents 1 and 2).

However, according to the conventional structure of the FeRAM, it is necessary to take margin in positioning a contact arranged at a side of the ferroelectric capacitor and connected to a source/drain region of the transistor and the ferroelectric capacitor. Therefore, there has been a problem that it is difficult to make memory cells compact.

To solve this problem, it is necessary to apply a method similar to a SAC (Self-Align Contact) technique of a DRAM to the contact at a side of the ferroelectric capacitor. However, when the SAC is simply applied to the ferroelectric capacitor, after a barrier film and an interlayer dielectric film are deposited on the ferroelectric capacitor, the interlayer dielectric film is etched in a state that the margin of positioning to the ferroelectric capacitor is set to zero or minus by lithography (first lithography). With this arrangement, a contact hole is opened using a barrier film as an etching stopper (first etching). A barrier film at a bottom of the contact hole is etched (second etching). At this time, a barrier film on a sidewall of the ferroelectric capacitor is remained. However, when the SAC is used, the barrier film on the sidewall of the ferroelectric capacitor is etched twice.

Further, the ferroelectric capacitor is usually in a tapered shape due to difficulty in processing the ferroelectric capacitor. Therefore, the barrier film on the sidewall of the ferroelectric capacitor is easily affected by the etching. As a result, the ferroelectric capacitor and the contact are short-circuited, or hydrogen barrier performance of the barrier film is degraded. This causes a degradation of an FeRAM.

### SUMMARY OF THE INVENTION

A semiconductor memory device according to an embodiment of the present invention includes a semiconductor substrate; a plurality of transistors provided on the semiconductor substrate; a plurality of ferroelectric capacitors provided on the plurality of transistors, the ferroelectric capacitors respectively including a ferroelectric film provided between a lower electrode and an upper electrode; and a barrier film covering a first side surface of the ferroelectric capacitor, and blocking passing of hydrogen, wherein

adjacent two of the ferroelectric capacitors connected in the lower electrode form one capacitor unit,

a plurality of the capacitor units connected in the upper electrode form one capacitor chain,

the capacitor units are arranged with a deviation of a half pitch of the capacitor unit in adjacent plurality of capacitor chains, and

when D1 is a distance between the adjacent ferroelectric capacitors within the capacitor unit, D2 is a distance between the adjacent capacitor chains, and D3 is a distance between the adjacent capacitor units within the capacitor chain, D3 is larger than D1 and D2.

A semiconductor memory device according to an embodiment of the present invention includes a semiconductor substrate; a plurality of transistors provided on the semiconductor substrate; a first conductive plug provided on one of a source layer and a drain layer of the transistor; a second conductive plug provided on the other of the source layer and the drain layer of the transistor; a plurality of ferroelectric capacitors respectively including a lower electrode electrically connected to the first conductive plug, a ferroelectric film provided on the lower electrode, and an upper electrode provided on the ferroelectric film; a barrier film respectively covering a first side surface of the lower electrode, the ferroelectric film, and the upper electrode, and blocking passing of hydrogen; a third conductive plug electrically connected to the second conductive plug, and facing the first side surface via the barrier film; and an electrode wiring electrically connecting between the upper electrode and the third conductive plug, wherein

adjacent two ferroelectric capacitors connected in the lower electrode form one capacitor unit,

a plurality of the capacitor units connected in the upper electrode form one capacitor chain,

the capacitor units are arranged with a deviation of a half pitch of the capacitor unit in a plurality of adjacent capacitor chains, and

when D1 is a distance between the adjacent ferroelectric capacitors within the capacitor unit, D2 is a distance between the adjacent capacitor chains, and D3 is a distance between the adjacent capacitor units within the capacitor chain, D3 is larger than D1 and D2.

A method of manufacturing a semiconductor memory device according to an embodiment of the present invention, the device comprising as a memory cell a ferroelectric capacitor including a ferroelectric film between a lower electrode and an upper electrode, wherein adjacent two of the ferroelectric capacitors connected in the lower electrode form one capacitor unit, a plurality of the capacitor units connected in the upper electrode form one capacitor chain, and the capacitor units are arranged with a deviation of a half pitch of the capacitor unit in adjacent plurality of capacitor chains, and

the method including: forming a plurality of transistors on a semiconductor substrate; forming a first conductive plug connected to one of a source layer and a drain layer of the transistor, the first conductive plug being positioned beneath an interval between the ferroelectric capacitors adjacent within the capacitor unit; forming a second conductive plug connected to the other of the source layer and the drain layer of the transistor, the second conductive plug being positioned beneath an interval between the capacitor units adjacent within the capacitor chain; forming a plurality of ferroelectric capacitors respectively including a lower electrode electrically connected to the first conductive plug, a ferroelectric film provided on the lower electrode, and an upper electrode provided on the ferroelectric film; depositing a barrier film to block passing of hydrogen so as to fill a trench between the adjacent ferroelectric capacitors within the capacitor unit and a trench between the adjacent capacitor chains, have a recess formed in a trench between the adjacent capacitor units, and cover a first side surface of the ferroelectric capacitor; exposing in self alignment the second conductive plug at the bottom of the trench between the adjacent capacitor units, while remaining the barrier film covering the first side surface, by anisotropically etching the barrier dielectric film; forming a third conductive plug electrically connected to the second conductive plug, by filling a conductor into the trench between the adjacent capacitor units; and forming an electrode wiring connecting the upper electrode and the third conductive plug.

### BRIEF DESCRIPTION OF THE DRAWINGS

FIG. 1 is a plan view showing one example of a configuration of a ferroelectric random access memory (FeRAM) according to the present embodiment;

FIG. 2 is a cross-sectional view along a line 2-2 in FIG. 1;

FIG. 3 is a plan view showing the method of manufacturing the FeRAM according to the present embodiment;

FIG. 4 is a cross-sectional view along a line 4-4 in FIG. 3;

FIG. 5 is a plan view showing the method of manufacturing the FeRAM continued from FIG. 3;

FIG. 6 is a cross-sectional view along a line 6-6 in FIG. 5;

FIG. 7 is a plan view showing the method of manufacturing the FeRAM continued from FIG. 5;

FIG. 8 is a cross-sectional view along a line 8-8 in FIG. 7;

FIG. 9 is a cross-sectional view showing the method of manufacturing the FeRAM continued from FIG. 8;

FIG. 10 is a cross-sectional view showing the method of manufacturing the FeRAM continued from FIG. 9;

FIG. 11 is a cross-sectional view showing the method of manufacturing the FeRAM continued from FIG. 10;

FIG. 12 is a cross-sectional view showing the method of manufacturing the FeRAM continued from FIG. 11; and

FIG. 13 is a cross-sectional view showing a modification of the present embodiment.

### DETAILED DESCRIPTION OF THE INVENTION

An embodiment of the present invention will be explained below in detail with reference to the accompanying drawings. Note that the invention is not limited to the embodiment.

A ferroelectric random access memory according to the present embodiment is a memory which consists of series connected memory cells each having a transistor having a source terminal and a drain terminal and a ferroelectric capacitor inbetween the two terminals, hereinafter named “Series connected TC unit type ferroelectric RAM”.

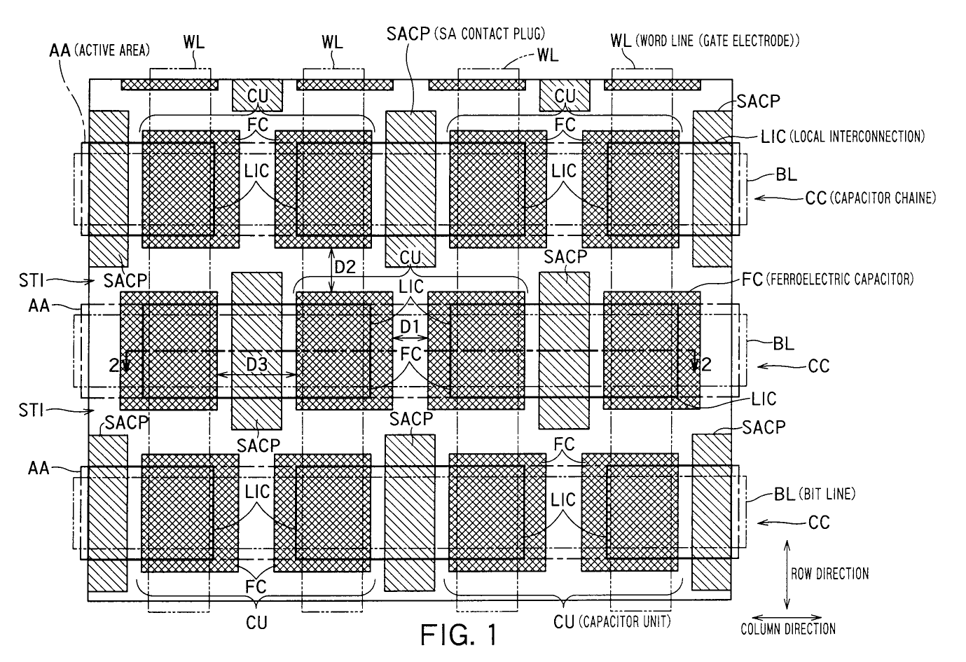

FIG. 1 is a plan view showing one example of a configuration of a ferroelectric random access memory (FeRAM) according to the present embodiment. Active areas AAs forming transistors are extended in a stripe shape to a column direction. Shallow trench isolations STIs are provided between the active areas AAs adjacent in a row direction. Plural bit lines BLs are extended in a stripe shape to a column direction, in a similar manner to that of the active areas AAs. Plural word line WLs are extended to a row direction substantially orthogonal with a column direction. That is, the bit lines BLs and the word lines WLs are orthogonal with each other.

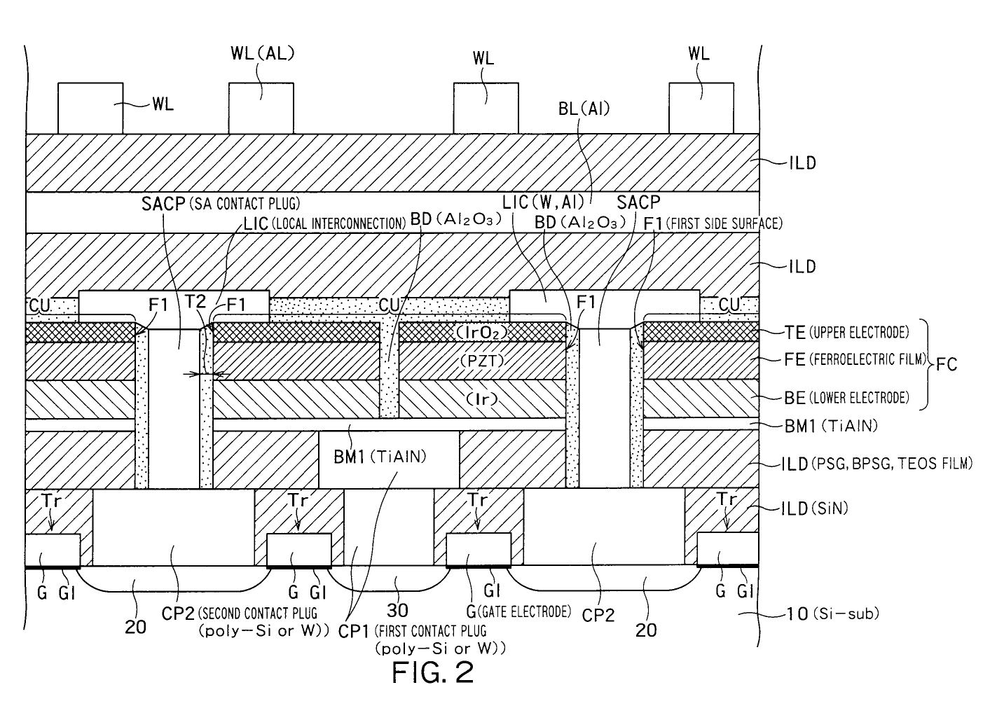

A ferroelectric capacitor FC is provided at each crossing of each word line WL and each bit line BL. Two ferroelectric capacitors FCs adjacent in a column direction form one capacitor unit CU. Two ferroelectric capacitors FCs within each capacitor unit CU are electrically connected to each other in lower electrodes (see FIG. 2). An electrode wiring LIC (Local InterConnect) connects between upper electrodes (see FIG. 2) of the ferroelectric capacitors FCs included in two capacitor units CUs adjacent in a column direction. Plural capacitor units CUs including two adjacent ferroelectric capacitors connected in the lower electrodes are connected in the upper electrodes by the electrode wirings LICs, thereby forming a capacitor chain CC. The capacitor chain CC is configured by the plural capacitor units CUs arranged in a column direction along the bit lines BLs.

An SA contact plug SACP is provided between two capacitor units CUs adjacent in a column direction and is also provided below the electrode wirings LICs. The SA contact plugs SACPs are provided to electrically connect between a source layer or a drain layer of transistors and the electrode wirings LICs. For example, the SA contact plugs SACPs are made of tungsten, titanium, or titanium nitride.

As shown in FIG. 1, between two capacitor chains CCs adjacent in a row direction, the capacitor units CU are arranged with a deviation of a half pitch. That is, in a certain capacitor chain CC, a position of each SA contact plug SACP corresponds to an intermediate position of the capacitor unit CU of the capacitor chain CC adjacent to this capacitor chain CC (a position of an interval between the two ferroelectric capacitors FCs within the capacitor unit CU). That is, because the capacitor unit CUs are arranged with a deviation of a half pitch in the adjacent capacitor chain CCs the capacitor units CUs, the SA contact plugs SACPs, and the electrode wirings LICs are formed in a zigzag plane structure.

FIG. 2 is a cross-sectional view along a line 2-2 in FIG. 1. The FeRAM includes a semiconductor substrate 10, plural transistors Trs provided on the semiconductor substrate 10, first contact plugs CP1s provided on a source layer or a drain layer 30 of each transistor Tr, and second contact plugs CP2s provided on the source layer or a drain layer 20 of each transistor Tr. The semiconductor substrate 10 is a silicon substrate, for example. Each transistor Tr can be an n-type MISFET (Metal-insulator-Semiconductor Field-Effect Transistor) or a p-type MISFET. The first and second contact plugs CP1s and CP2s are made of a conductive material such as polysilicon or tungsten. Diffusion layers 20 and 30 can be source layers or drain layers.

A gate dielectric film GI is provided on a channel between the diffusion layers 20 and 30, and a gate electrode G is provided on each gate dielectric film GI. The gate electrodes Gs are extended to a row direction shown in FIG. 1, and also function as a word line. Interlayer dielectric films ILDs are provided around the gate electrodes Gs. Each interlayer dielectric film ILD consists of, for example, a BPSG, PSG, or TEOS film or a silicon nitride film.

The first contact plugs CP1s and the second contact plugs CP2s are embedded into the interlayer dielectric films ILDs. First barrier metals BM1s are provided on the first contact plugs CP1s. The first barrier metal BM1s are formed by a conductive material (TiAlN, for example) not passing hydrogen generated by plasma CVD (Chemical Vapor Deposition) or the like.

The ferroelectric capacitors FCs are provided on the first barrier metals BM1s. More specifically, iridium Ir is provided on the first barrier metal BM1s, for lower electrodes BEs, for example. PZT (Pb (Zrₓ, Ti₁₋ₓ) O₃), SBT (SrBi₂Ta₂O₉) are provided on the lower electrodes BEs, for ferroelectric films FEs, for example. Iridium oxide IrO₂ is provided on the ferroelectric films FEs, for the upper electrode, for example.

Two adjacent ferroelectric capacitors FCs constitute the capacitor unit CU. The lower electrodes BEs of the two ferroelectric capacitors FCs included in the same capacitor unit CU are connected to the first contact plugs CP1s via the first barrier metals BM1s. That is, the lower electrodes BEs of the two ferroelectric capacitors FCs included in the same capacitor unit CU are electrically connected in common to the diffusion layer 30.

A barrier dielectric film BD is provided between the two ferroelectric capacitors FCs included in the same capacitor unit CU. The barrier dielectric film BD is formed by a nonconductive material (aluminum (Al₂O₃), for example) not passing hydrogen. The barrier dielectric film BD covers each side surface (first side surface F1) of the opposite ferroelectric capacitors between the two adjacent capacitor units CUs. When the barrier dielectric film BD covers each first side surface F1 of the lower electrodes BEs, the ferroelectric films FEs, and upper electrodes TEs, respectively, penetration of hydrogen into the ferroelectric films FEs can be prevented.

The SA contact plugs SACPs are provided as third contact plugs between the two adjacent capacitor units CUs. The SA contact plugs SACPs are made of a metal such as aluminum or tungsten, for example. Each SA contact plug SACP faces the first side surface F1 of the ferroelectric capacitor FC via the barrier dielectric film BD. The SA contact plugs SACPs are provided on the second contact plugs CP2s and are connected to the second contact plugs CP2s.

The electrode wirings LICs are provided on the SA contact plugs SACPs, and on the upper electrodes TEs. The electrode wirings LICs are made of a metal such as aluminum or tungsten, for example. Each electrode wiring LIC connects two upper electrodes TEs included in the two adjacent capacitor units CUs to the SA contact plug SACP. That is, the electrode wiring LIC electrically connects in common the upper electrodes TEs of the two ferroelectric capacitors FCs facing each other on the first side surface F1, via the second contact plug.

The barrier dielectric film BD is present between the electrode wirings LICs. The bit lines BLs are provided on the electrode wirings LICs via the interlayer dielectric films ILDs. The word lines WLs are provided on the bit lines BLs via the interlayer dielectric films ILDs. The bit lines BLs and the word lines WLs are made of a metal such as aluminum or tungsten, for example. The word lines WLs are provided corresponding to each gate electrode G, and are provided to decrease gate resistance.

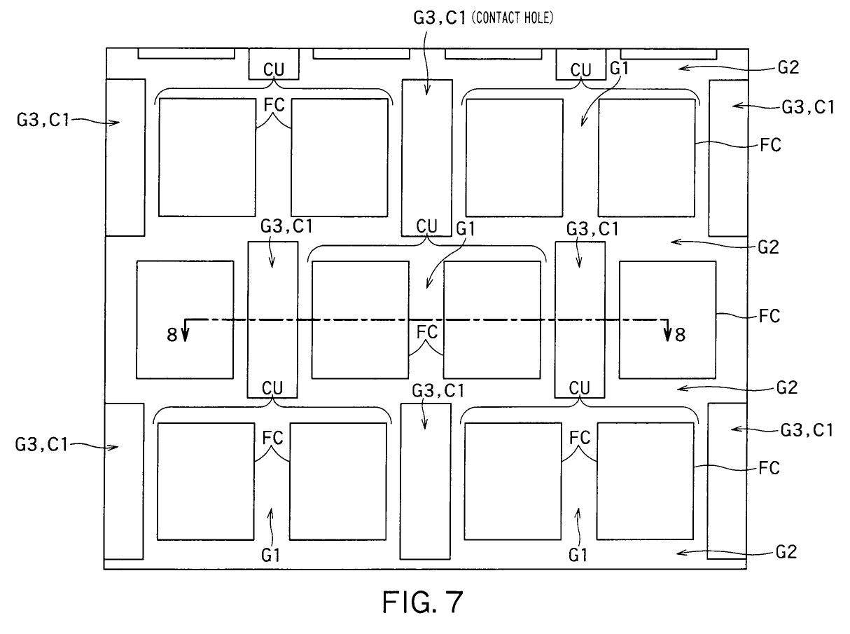

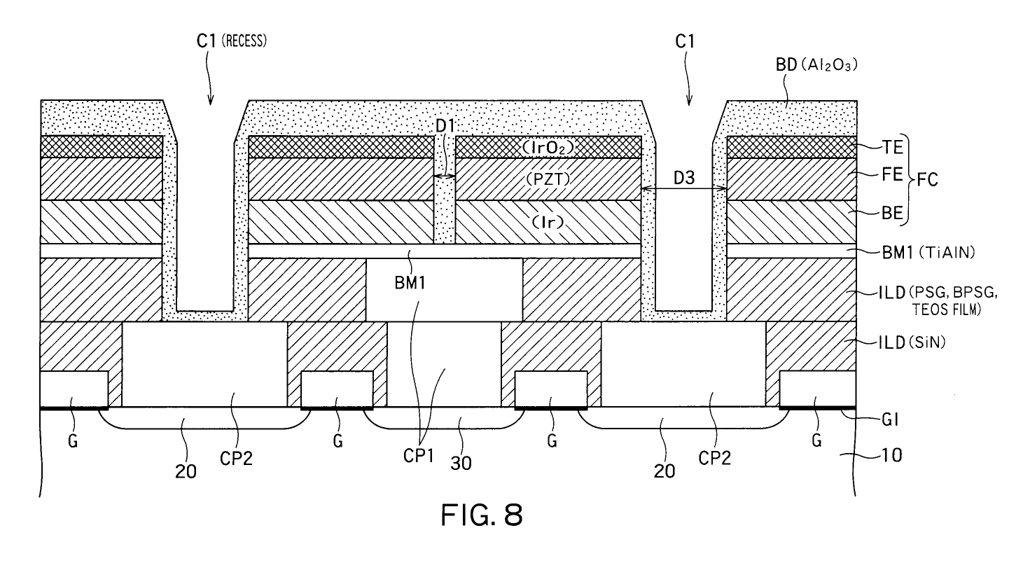

In the present embodiment, a distance between the two ferroelectric capacitors FCs adjacent within the same capacitor unit CU is set as D1. A distance between the two adjacent capacitor chains CCs is set as D2. A distance between the two capacitor units CUs adjacent within the capacitor chain CC is set as D3. In this case, D3 is larger than any one of D1 and D2. As a result, the SA contact plugs SACPs can be easily formed in self alignment between the capacitor units CUs. A film thickness T1 of the barrier dielectric film BD deposited on the first side surface F1 becomes larger than (½)*D1 and (½)*D2, and smaller than (½)*D3. As a result, an interval between the two ferroelectric capacitors FCs adjacent within the same capacitor unit CU and an interval between the two adjacent capacitor chains CCs are filled by the barrier dielectric film BD. On the other hand, an interval between the two capacitor units CUs adjacent within the capacitor chain CC is not filled by the barrier dielectric film BD, and a center portion is caved, and recesses C1s are formed (FIG. 7 and FIG. 8). In this state, the whole surface of the barrier dielectric film BD is etched back to remove only the barrier dielectric film BD of the recesses C1s, by remaining the barrier dielectric film BD deposited on the side surface F1 of the ferroelectric capacitor FC. As a result, the upper surface of the second contact plugs CP2s can be exposed in self alignment. By embedding a conductive material into the recesses C1s (an interval between the two adjacent capacitor units CUs), the SA contact plugs SACPs can be formed in self alignment so that the SA contact plugs SACPs are insulated from the first side surface F1 of the ferroelectric capacitors FCs and are also connected to the second contact plugs CP2s.

In the present embodiment, the capacitor units CUs are deviated by a half pitch between the adjacent capacitor chains CCs. If there is not this deviation, the SA contact plugs SACPs are connected in a row direction along the word lines WLs. That is, the SA contact plugs SACPs are connected between the capacitor chains CCs. In this state, memory cells of each column cannot be operated accurately. Based on the arrangement in the present embodiment that the capacitor units CUs are deviated by a half pitch between the adjacent capacitor chains CCs, the SA contact plugs SACPs can be isolated in the capacitor chains CCs in each column. As a result, the memory cells of each column can be operated accurately.

A method of manufacturing the FeRAM according to the present embodiment is explained next.

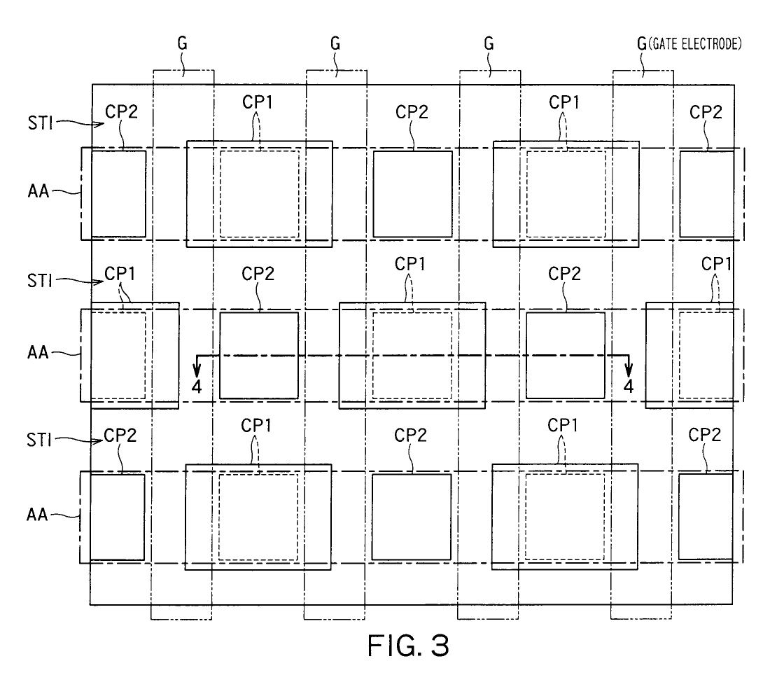

FIG. 3 is a plan view showing the method of manufacturing the FeRAM according to the present embodiment. FIG. 3 is a schematic view, and a size of each constituent element is different from an actual size is some cases. The first contact plugs CP1s and the second contact plugs CP2s are arranged with a deviation of a half pitch in each adjacent active area AA. Therefore, in the adjacent active area AA, the first contact plugs CP1s are adjacent to the second contact plugs CP2s, and the second contact plugs CP2s are adjacent to the first contact plugs CP1s.

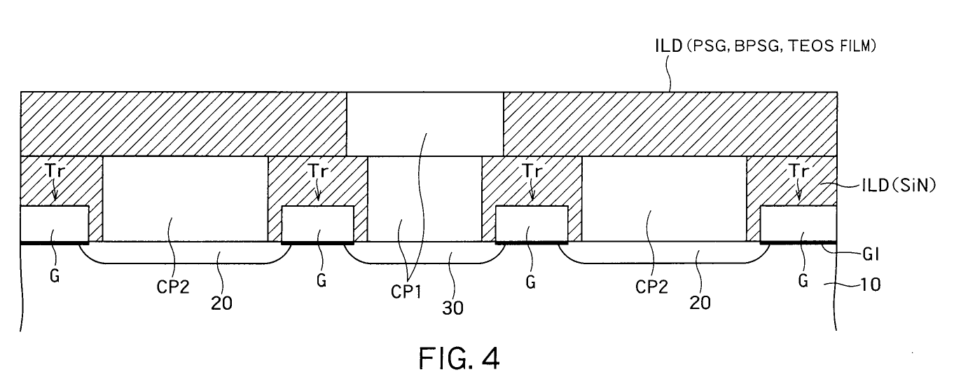

FIG. 4 is a cross-sectional view along a line 4-4 in FIG. 3. First, the transistors Trs are formed on the semiconductor substrate 10 using a known manufacturing process. More specifically, the gate dielectric films GIs are formed on the semiconductor substrate 10, and the gate electrodes Gs are formed on the gate dielectric films GIs. An impurity is implanted into the surface of the semiconductor substrate 10, using the gate electrodes Gs as a mask. The impurity is activated by heat treatment, thereby forming the diffusion layers 20 and 30.

Next, silicon nitride films are deposited on the transistors Trs as a material of the interlayer dielectric films ILDs, using LP (Low Pressure)-CVD or plasma CVD. A film thickness of each silicon nitride film is a few hundred angstroms, for example. The silicon nitride films are flattened using CMP (Chemical-Mechanical Polishing). By removing the silicon nitride films on the diffusion layers 20 and 30 using lithography and RIE (Reactive Ion Etching), contact holes are formed. Polysilicon or tungsten is filled into the contact holes using a damascene method, thereby forming a lower part of the first contact plugs CP1s and the second contact plugs CP2s. The lower part of the first contact plugs CP1s is positioned beneath the interval between the ferroelectric capacitors FCs adjacent within the capacitor unit CU. The second contact plugs CP2s are positioned beneath the interval between the capacitor units CUs adjacent within the capacitor chain CC.

A PSG film, a BPSG film, or a TEOS film, or a laminated film (hereinafter, an oxide film) of these films as a material of the interlayer dielectric films ILDs is deposited on the silicon nitride films, and the first and second contact plugs CP1s and CP2s, using the LP-CVD method or the plasma CVD method. The oxide film is flattened using CMP. The oxide film on the first contact plugs CP1s is removed using lithography or RIE, thereby forming contact holes. Polysilicon or tungsten is filled into the contact holes using a damascene method, thereby forming an upper part of the first contact plugs CP1s.

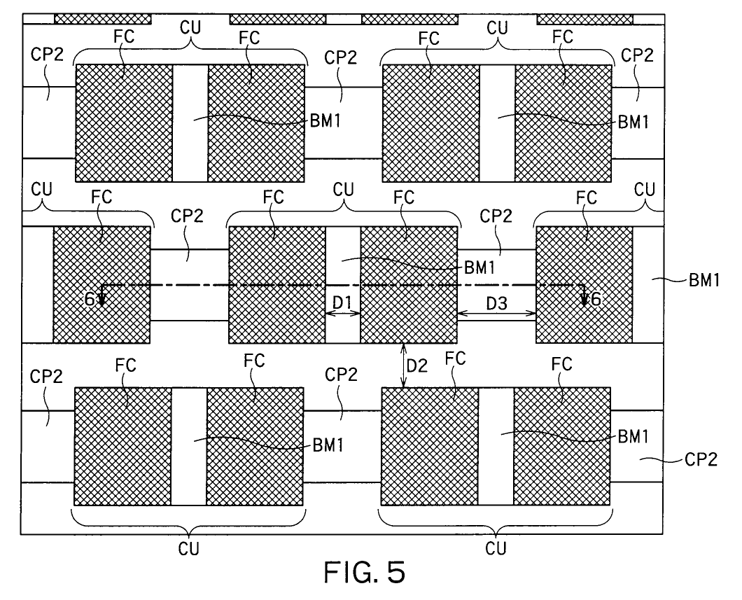

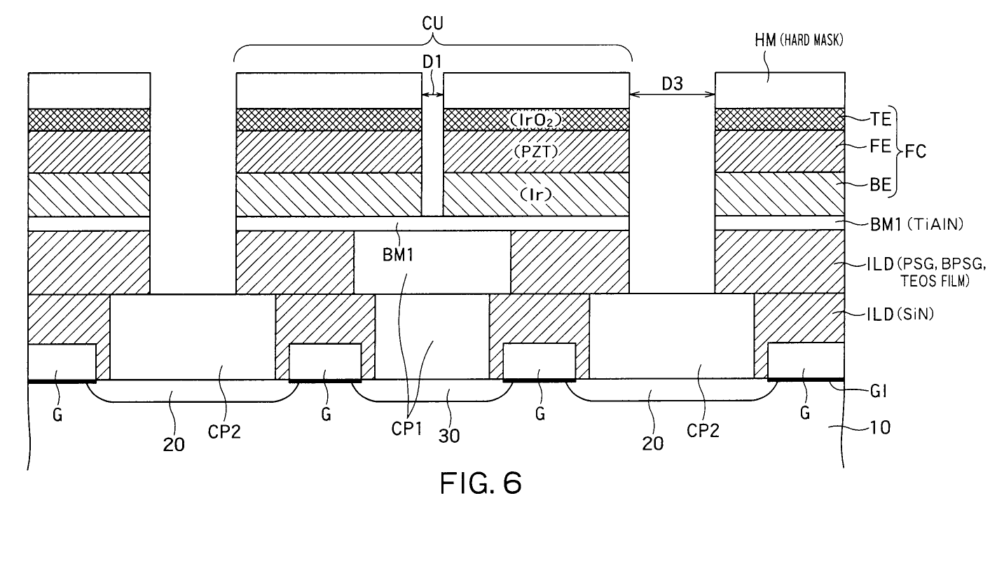

FIG. 5 is a plan view showing the method of manufacturing the FeRAM continued from FIG. 3. FIG. 6 is a cross-sectional view along a line 6-6 in FIG. 5. TiAlN is deposited as a material of the first barrier metals BM1s on the interlayer dielectric films ILDs and the first contact plugs CP1s, using the sputtering method.

Next, iridium Ir is deposited as a material of the lower electrodes BEs on the first barrier metals BM1s, using the sputtering method or the like. PZT or SBT is deposited as the ferroelectric films FEs, using the sputtering method, the MO (Metal Organic) CVD method, or a sol-gel process. Iridium oxide IrO₂ as a material of the upper electrodes TEs is deposited on the ferroelectric films FEs, using the sputtering method or the like.

Next, a TEOS film is deposited as a material of a hard mask HM, using the plasma CVD method. The TEOS film is processed to cover the individual ferroelectric capacitors FCs, using the lithography and the RIE. That is, the TEOS film is processed on a plane pattern of the ferroelectric capacitors FCs. Next, the upper electrodes TEs, the ferroelectric films FEs, and the lower electrodes BEs are etched by the RIE method, using the hard mask made of the TEOS film as a mask. As a result, each ferroelectric capacitor FC is individualized. After the process, preferably, the hard mask HM remains by about 1,000 angstroms. At this stage, the first barrier metals BM1s are exposed in regions other than the ferroelectric capacitors FCs.

Next, the regions of the capacitor units CUs are covered by a mask material, using lithography, and the first barrier metals BM1s and the interlayer dielectric films ILDs in regions other than the capacitor units CUs are removed, using RIE. As a result, the first barrier metals BM1s remain within the capacitor units CUs, and the first barrier metals BM1s in other regions than the capacitor units CUs are removed. As shown in FIG. 6, the upper parts of the interlayer dielectric films ILDs in other regions than the capacitor units CUs are removed. As a result, the second contact plugs CP2s are exposed between the two capacitor units CUs adjacent in a column direction.

FIG. 7 is a plan view showing the method of manufacturing the FeRAM continued from FIG. 5. FIG. 8 is a cross-sectional view along a line 8-8 in FIG. 7. The barrier dielectric film BD is deposited on the structures shown in FIG. 5 and FIG. 6, using the sputtering method or the ALD (Atomic Layer Deposition) method. The barrier dielectric film BD is made of aluminum (Ai₂O₃), for example. In this case, the film thickness T1 of the barrier dielectric film BD deposited on the first side surface F1 of the Ferroelectric capacitors FCs is larger than (½)*D1 and (½)*D2, and smaller than (½)*D3. For example, D1 is 80 nm, D2 is 120 nm, D3 is 240 nm, and the film thickness T1 is 70 nm. As a result, the interval G1 between the two ferroelectric capacitors FCs adjacent within the same capacitor unit CU, and the interval G2 between the two adjacent capacitor chains CCs are filled by the barrier dielectric film BD. However, the interval G3 between the two capacitor units CUs adjacent within the capacitor chain CC is not filled by the barrier dielectric film BD, and the center portion is caved, and the recesses C1s are formed. In this state, the barrier dielectric film BD covers the first side surface F1.

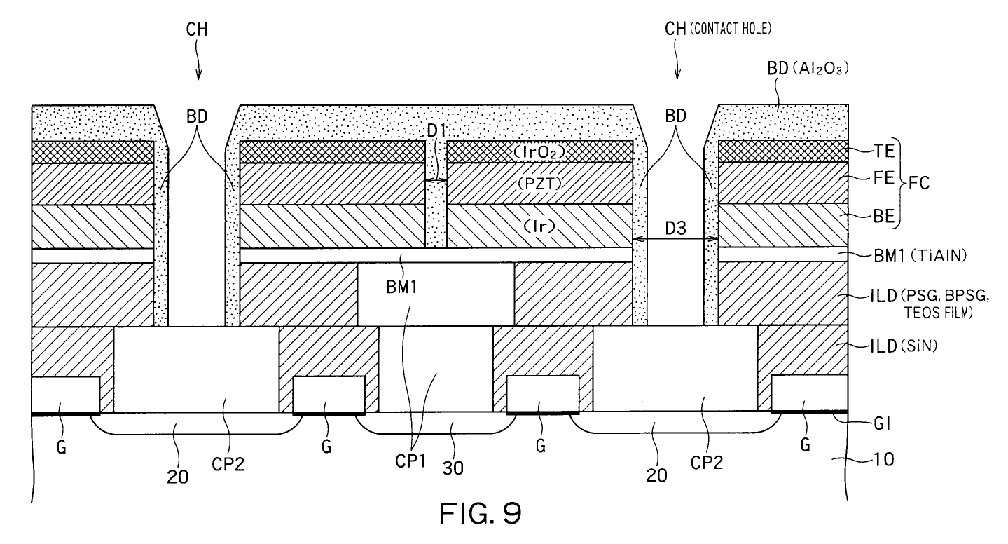

Next, the whole surface of the barrier dielectric film BD is etched back anisotropically. In this case, because the intervals G1 and G2 are filled by the barrier dielectric film BD, the thickness (depth) of the barrier dielectric film BD in the intervals G1 and G2 is large (deep). On the other hand, while the sidewall of the interval G3 is covered by the barrier dielectric film BD, the interval G3 is not filled. Therefore, the thickness (depth) of the barrier dielectric film BD at the bottom of the recesses C1s is much smaller (shallower) than the thickness (depth) of the barrier dielectric film BD in the intervals G1 and G2. Consequently, by anisotropically etching back the whole surface of the barrier dielectric film BD, only the barrier dielectric film BD of the recesses C1s is removed, by remaining the barrier dielectric film BD deposited on the side surface F1 of the ferroelectric capacitor FC. That is, by anisotropically etching back the barrier dielectric film BD, only the second contact plugs CP2s are exposed in self alignment, without exposing the first side surface and the upper electrodes TEs. As a result, contact holes CHs communicating to the second contact plugs CP2s are formed between the adjacent capacitor units CUs as shown in FIG. 9. In this etch back process, etching only the thin barrier dielectric film BD at the bottom of the recesses C1s is sufficient. In this case, the etching of the barrier dielectric film BD can be finished in a short time. Therefore, insulation (coating) of the barrier dielectric film BD deposited on the first side surface F1 of the ferroelectric capacitors FCs can be avoided from being degraded.

At this stage, the interlayer dielectric film is not deposited on the barrier dielectric film BD, and the contact holes are not necessary to be formed on the interlayer dielectric film. As a result, in the present embodiment, the first lithography and the first etching are not necessary, and the contact holes CHs are formed by only the second etching.

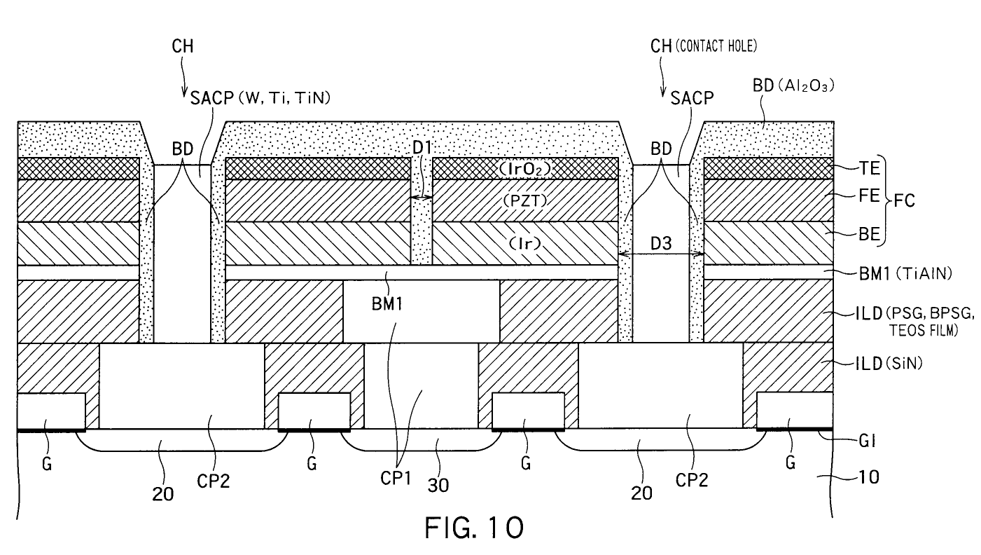

Next, as shown in FIG. 10, the SA contact plugs SACPs are deposited within the contact holes CHs. The SA contact plugs SACPs are made of tungsten, titanium, or titanium nitride, for example. The SA contact plugs SACPs are connected to the second contact plugs CP2s beneath them. As explained above, in the present embodiment, the contact holes CHs and the SA contact plugs SACPs are formed in self alignment without using lithography.

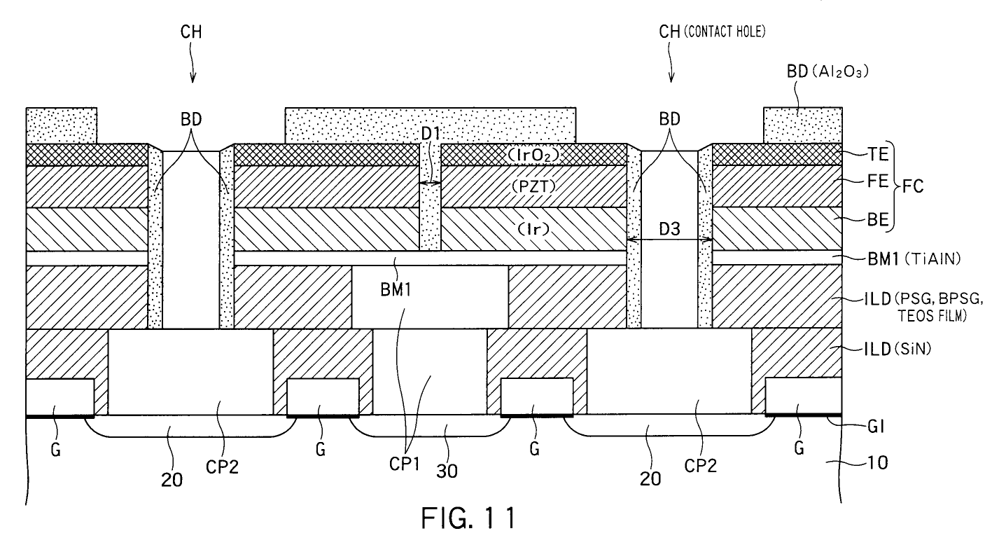

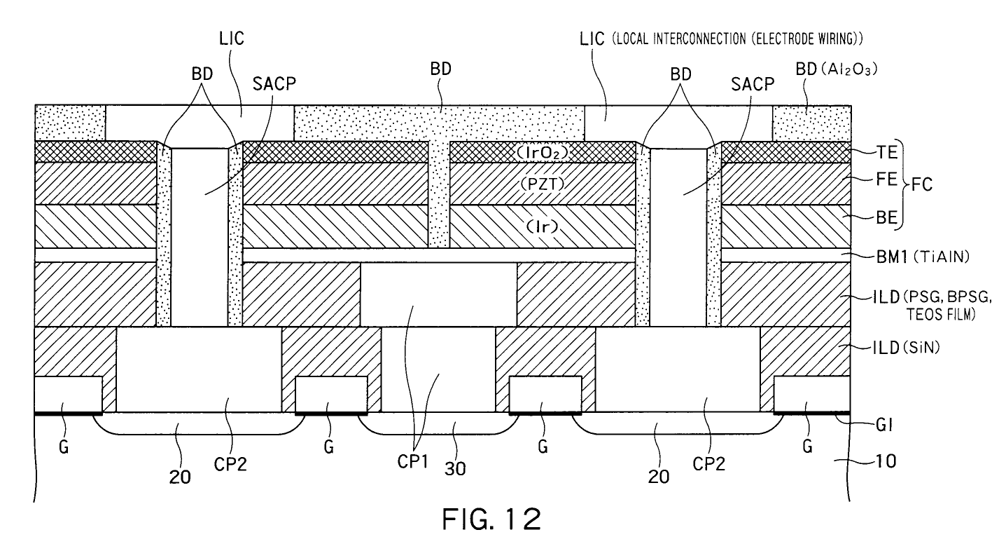

Next, the barrier dielectric film BD on the upper electrodes TEs is processed as shown in FIG. 11, using lithography and RIE. Aluminum or tungsten is deposited as a material of the electrode wirings LICs, on the SA contact plugs SACPs, the upper electrodes TEs, and the barrier dielectric film BD. This aluminum or tungsten is flattened until when the barrier dielectric film BD is exposed, using CMR As a result, as shown in FIG. 12, the electrode wirings LICs are formed to connect between the two upper electrodes TEs at both sides of the SA contact plugs SACPs and the SA contact plugs SACPs. As explained above, the upper electrodes TEs are electrically connected to the diffusion layer 20 via the electrode wirings LICs, the SA contact plugs SACPs, and the second contact plugs CP2s.

Thereafter, the bit lines BLs, the word liens WLs, and the interlayer dielectric films ILDs are formed through a known process, thereby completing the FeRAM according to the present embodiment.

### MODIFICATION OF THE EMBODIMENT

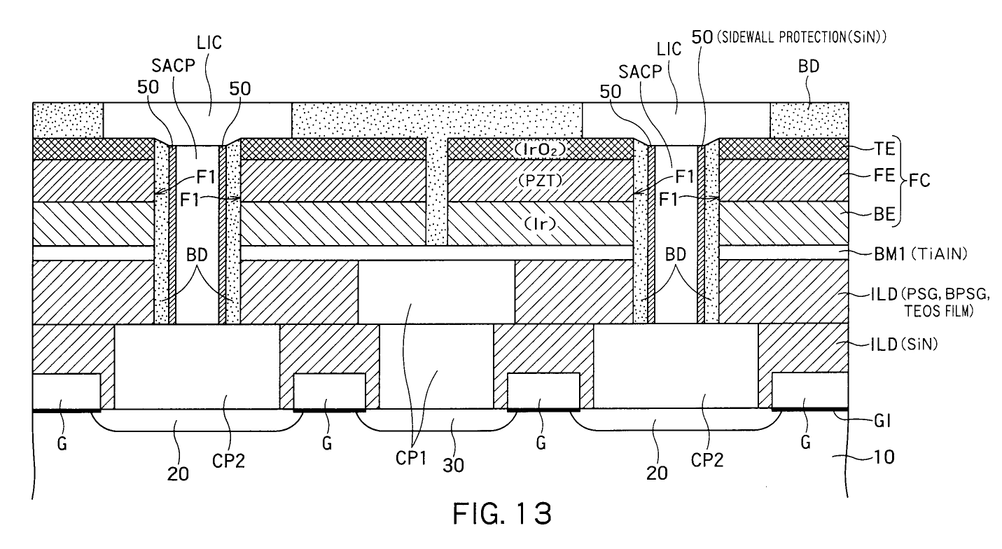

As a modification of the present embodiment, as shown in FIG. 13, sidewall protection films 50 can be provided between the barrier dielectric film BD covering the first side surface F1 of the ferroelectric capacitors FCs and the SA contact plugs SACPs. Preferably, the sidewall protection films 50 are materials having etching proof against an etching liquid solution of oxygen or alkali. For example, the sidewall protection films 50 can be dielectric films of silicon nitride films or the like, or can be nonconductive metals such as titanium nitride TiN. The sidewall protection films 50 are deposited on the barrier dielectric film BD after depositing the material of the barrier dielectric film BD and before etching back the material of the barrier dielectric film BD. Thereafter, the sidewall protection films 50 and the barrier dielectric film BD are continuously etched back. With this arrangement, at the time of etching back, the sidewall protection films 50 can protect the barrier dielectric film BD. As a result, the contact holes CHs can be formed without degrading hydrogen barrier performance of the barrier dielectric film BD.

In the above embodiment, the contact holes CHs and the SA contact plugs SACPs are formed in self alignment. Therefore, the lithography process to form the contact holes CHs becomes unnecessary. As described above, the barrier dielectric film BD etched back at the time of forming the contact holes CHs to form the contact holes CHs is only the thin part deposited on the bottom of the recesses C1. Consequently, the barrier dielectric film BD (or the sidewall protection films 50) deposited on the first side surface F1 of the ferroelectric capacitors F1s takes a smaller etching damage due to the etching back of the barrier dielectric film BD than a damage conventionally taken. Because it is sufficient to etch back only the thin barrier dielectric BD at the bottom of the recesses C1s at the time of forming the contact holes CHs, the contact holes CHs and the SA contact plugs SACPs can be formed easily. As a result, the method of manufacturing the FeRAM becomes simpler than the conventional method. Because the barrier dielectric film BD etched back at the time of forming the contact holes CHs is very thin, a contact defect does not occur easily, and contact resistance can be maintained low.

1. A semiconductor memory device comprising:
a semiconductor substrate;
a plurality of transistors provided on the semiconductor substrate;
a plurality of ferroelectric capacitors provided on the plurality of transistors, the ferroelectric capacitors respectively including a ferroelectric film provided between a lower electrode and an upper electrode; and
a barrier film covering a first side surface of the ferroelectric capacitor, and blocking passing of hydrogen, wherein
adjacent two of the ferroelectric capacitors connected in the lower electrode form one capacitor unit,
a plurality of the capacitor units connected in the upper electrode form one capacitor chain,
the capacitor units are arranged with a deviation of a half pitch of the capacitor unit in adjacent plurality of capacitor chains, and
when D1 is a distance between the adjacent ferroelectric capacitors within the capacitor unit, D2 is a distance between the adjacent capacitor chains, and D3 is a distance between the adjacent capacitor units within the capacitor chain, D3 is larger than D1 and D2.

2. The semiconductor memory device according to claim 1, wherein a film thickness of the barrier film is larger than (½)*D1 and (½)*D2, and smaller than (½)*D3.

3. The semiconductor memory device according to claim 1, wherein the barrier film fills a trench between the adjacent ferroelectric capacitors and a gap between the adjacent capacitor chains, and does not fill a gap between the adjacent capacitor units.

4. The semiconductor memory device according to claim 2, wherein the barrier film fills a trench between the adjacent ferroelectric capacitors and a gap between the adjacent capacitor chains, and does not fill a gap between the adjacent capacitor units.

5. A semiconductor memory device comprising:
a semiconductor substrate;
a plurality of transistors provided on the semiconductor substrate;
a first conductive plug provided on one of a source layer and a drain layer of the transistor;
a second conductive plug provided on the other of the source layer and the drain layer of the transistor;
a plurality of ferroelectric capacitors respectively including a lower electrode electrically connected to the first conductive plug, a ferroelectric film provided on the lower electrode, and an upper electrode provided on the ferroelectric film;
a barrier film respectively covering a first side surface of the lower electrode, the ferroelectric film, and the upper electrode, and blocking passing of hydrogen;
a third conductive plug electrically connected to the second conductive plug, and facing the first side surface via the barrier film; and
an electrode wiring electrically connecting between the upper electrode and the third conductive plug, wherein
adjacent two ferroelectric capacitors connected in the lower electrode form one capacitor unit,
a plurality of the capacitor units connected in the upper electrode form one capacitor chain,
the capacitor units are arranged with a deviation of a half pitch of the capacitor unit in a plurality of adjacent capacitor chains, and
when D1 is a distance between the adjacent ferroelectric capacitors within the capacitor unit, D2 is a distance between the adjacent capacitor chains, and D3 is a distance between the adjacent capacitor units within the capacitor chain, D3 is larger than D1 and D2.

6. The semiconductor memory device according to claim 5, wherein a film thickness of the barrier film is larger than (½)*D1 and (½)*D2, and smaller than (½)*D3.

7. The semiconductor memory device according to claim 5, wherein the barrier film fills a trench between the adjacent ferroelectric capacitors and a gap between the adjacent capacitor chains, and does not fill a gap between the adjacent capacitor units.

8. The semiconductor memory device according to claim 6, wherein the barrier film fills a trench between the adjacent ferroelectric capacitors and a gap between the adjacent capacitor chains, and does not fill a gap between the adjacent capacitor units.

9. A method of manufacturing a semiconductor memory device, which comprises as a memory cell a ferroelectric capacitor including a ferroelectric film between a lower electrode and an upper electrode, wherein
adjacent two of the ferroelectric capacitors connected in the lower electrode form one capacitor unit, a plurality of the capacitor units connected in the upper electrode form one capacitor chain, and the capacitor units are arranged with a deviation of a half pitch of the capacitor unit in adjacent plurality of capacitor chains, and
the method includes:
forming a plurality of transistors on a semiconductor substrate;
forming a first conductive plug connected to one of a source layer and a drain layer of the transistor, the first conductive plug being positioned beneath an interval between the ferroelectric capacitors adjacent within the capacitor unit;
forming a second conductive plug connected to the other of the source layer and the drain layer of the transistor, the second conductive plug being positioned beneath an interval between the capacitor units adjacent within the capacitor chain;
forming a plurality of ferroelectric capacitors respectively including a lower electrode electrically connected to the first conductive plug, a ferroelectric film provided on the lower electrode, and an upper electrode provided on the ferroelectric film;
depositing a barrier film to block passing of hydrogen so as to fill a trench between the adjacent ferroelectric capacitors within the capacitor unit and a trench between the adjacent capacitor chains, have a recess formed in a trench between the adjacent capacitor units, and cover a first side surface of the ferroelectric capacitor;
exposing in self alignment the second conductive plug at the bottom of the trench between the adjacent capacitor units; while remaining the barrier film covering the first side surface, by anisotropically etching the barrier film;
forming a third conductive plug electrically connected to the second conductive plug, by filling a conductor into the trench between the adjacent capacitor units; and
forming an electrode wiring connecting the upper electrode and the third conductive plug.

10. The method according to claim 9, wherein
when D1 is a distance between the adjacent ferroelectric capacitors within the capacitor unit, D2 is a distance between the adjacent capacitor chains, and D3 is a distance between the adjacent capacitor units within the capacitor chain, D3 is larger than D1 and D2.

11. The method according to claim 10, wherein a film thickness of the barrier film is larger than (½)*D1 and (½)*D2, and smaller than (½)*D3.

12. The method according to claim 10, wherein the barrier film fills a trench between the adjacent ferroelectric capacitors and a gap between the adjacent capacitor chains, and does not fill a gap between the adjacent capacitor units.

13. The method according to claim 11, wherein the barrier film fills a trench between the adjacent ferroelectric capacitors and a gap between the adjacent capacitor chains, and does not fill a gap between the adjacent capacitor units.
